(19) United States
(12) Patent Application Publication
(10) Pub. No.: US 2003/0124842 A1
(43) Pub. Date: Jul. 3, 2003

(54) Dual-gas delivery system for chemical vapor deposition processes

(75) Inventors: Mark M. Hytros, Santa Clara, CA (US); Truc T. Tran, Fremont, CA (US); Salvador P. Umotoy, Antioch, CA (US); Lawrence Chung-Lai Lei, Milpitas, CA (US); Avgerinos Gelatos, Redwood City, CA (US); Tong Zhang, Palo Alto, CA (US)

Correspondence Address: APPLIED MATERIALS, INC., 2881 SCOTT BLVD. M/S 2061, SANTA CLARA, CA, 95050, US

(73) Assignee: APPLIED MATERIALS, INC.

(21) Appl. No.: 10/033,544

(22) Filed: Dec. 27, 2001

(51) Int. Cl. C23F 1/00; C23C 16/00; H01L 21/306; H01L 21/44

(52) U.S. Cl. 438/680; 156/345.33; 118/715

(57) ABSTRACT

Embodiments of the present invention generally relate to an apparatus and method for delivering two separate gas flows to a processing region. One embodiment of a substrate processing chamber adapted to deliver two separate gas flows to a processing region comprises a substrate support having a substrate receiving surface and a showerhead disposed over the substrate receiving surface. The showerhead includes a first passageway having a plurality of first passageway holes and a second passageway having a plurality of second passageway holes. The first passageway is adapted to deliver a first gas flow through the first passageway holes to the substrate receiving surface. The second passageway is adapted to deliver a second gas flow through the second passageway holes to the substrate receiving surface. The substrate processing chamber further includes a plasma power source. The plasma power source may be in electrical communication with the showerhead or with the substrate support to generate a plasma from gases between the showerhead and the substrate support. One embodiment of a method of delivering two separate gas flows to a processing region comprises performing one or more of processes from the group including forming a titanium layer by plasma enhanced chemical vapor deposition, forming a passivation layer by a nitrogen plasma treatment of a titanium layer, forming a composite titanium/titanium nitride layer by an alternating plasma enhanced chemical vapor deposition and a nitrogen plasma treatment, forming a titanium nitride layer by thermal chemical vapor deposition, and plasma treating a titanium nitride layer.

### BACKGROUND OF THE INVENTION

1. Field of the Invention

Embodiments of the present invention generally relate to an apparatus and method for delivering at least two separate gas flows to a processing region.

2. Description of the Related Art

Semiconductor processing chambers are used to provide process environments for the fabrication of integrated circuits on semiconductor substrates. Typically, in the manufacture of integrated circuits, multiple layers, such as metal layers, dielectric layers, and barrier layers, are deposited over a substrate. Chemical vapor deposition is one deposition technique for depositing a layer of material over a substrate.

FIG. 1 is a schematic cross-sectional view of a prior art chamber 10 adapted for chemical vapor deposition. The chamber 10 includes a showerhead 40 and a substrate support 32 for supporting a substrate 36. The showerhead 40 has a central gas inlet 44 for the injection of gases and has a plurality of holes 42 to accommodate the flow of gases therethrough. The plurality of holes 42 are arranged on the showerhead 40 to provide a substantially uniform flow of gases over the substrate 36. For plasma processes, a power source 70, such as an RF power source, is coupled to the showerhead 40 to create an electric field between the showerhead 40 and the substrate support 32 generating a plasma 80 from the gases flowing therebetween. One problem with the use of prior chambers, such as chamber 10, is delivering two or more reactive gases through the showerhead 40. The gases may react and form particles within the showerhead 40. Therefore, there is a need for an improved apparatus and method of delivering two separate gas flows to a processing region.

### SUMMARY OF THE INVENTION

Embodiments of the invention generally relate to an apparatus and method for delivering two separate gas flows to a processing region. One embodiment of a gas delivery system adapted to deliver two separate gas flows to a processing region includes a gas box, a blocker plate disposed below the gas box, and a showerhead disposed below the blocker plate. The gas box comprises a first gas channel having a first outlet and a second gas channel having a second gas outlet. The gas box may further comprise a temperature fluid control channel. The blocker plate comprises a plurality of blocker plate holes formed therethrough. The showerhead comprising columns having column holes in communication with a top surface and a bottom surface of the showerhead and interconnected grooves having groove holes in communication with the bottom surface of the showerhead. The first outlet of the gas box is adapted to supply a first gas through the blocker plate holes of the blocker plate to the column holes of the showerhead. The second gas outlet of the gas box is coupled to the showerhead and is adapted to supply a second gas through the interconnect grooves of the showerhead to the groove holes of the showerhead.

One embodiment of a substrate processing chamber adapted to deliver two separate gas flows to a processing region comprises a substrate support having a substrate receiving surface and a showerhead disposed over the substrate receiving surface. The showerhead includes a first passageway having a plurality of first passageway holes and a second passageway having a plurality of second passageway holes. The first passageway is adapted to deliver a first gas flow through the first passageway holes to the substrate receiving surface. The second passageway is adapted to deliver a second gas flow through the second passageway holes to the substrate receiving surface. The substrate processing chamber further includes a plasma power source. The plasma power source may be in electrical communication with the showerhead or with the substrate support to generate a plasma from gases between the showerhead and the substrate support.

One embodiment of a method of delivering two separate gas flows to a processing region comprises performing one or more of processes from the group including forming a titanium layer by plasma enhanced chemical vapor deposition, forming a passivation layer by a nitrogen plasma treatment of a titanium layer, forming a composite titanium/titanium nitride layer by an alternating plasma enhanced chemical vapor deposition and a nitrogen plasma treatment, forming a titanium nitride layer by thermal chemical vapor deposition, and plasma treating a titanium nitride layer.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIG. 1 is a schematic cross-sectional view of a prior art chamber adapted for chemical vapor deposition.

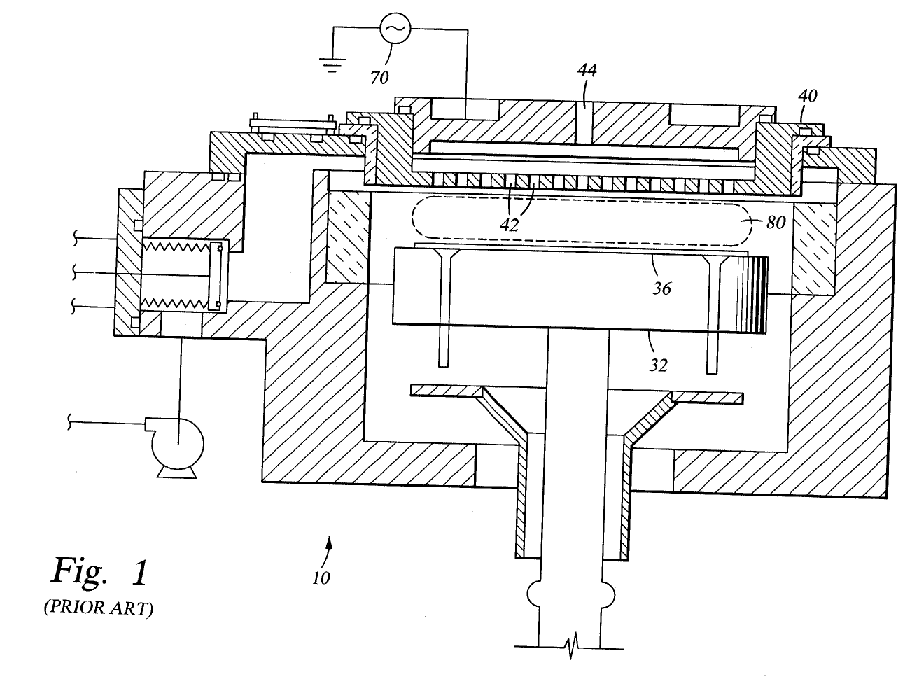

FIG. 2 is a schematic cross-sectional view of one embodiment of a chamber adapted to deliver two separate gas flows to a processing region.

FIG. 3 is an exploded top perspective view of a top plate and a center plate of the gas box of FIG. 2.

FIG. 4 is an exploded bottom perspective view of the center plate and the bottom plate of the gas box of FIG. 2.

FIG. 5 is a schematic cross-sectional view of the showerhead of FIG. 2.

FIG. 6 is a top schematic view of the second plate of the showerhead of FIG. 2

FIG. 7 is an exploded perspective view of the gas box and the showerhead.

FIGS. 8A-F are cross-sectional views of a substrate illustrating various exemplary embodiments of applications of a titanium layer and/or a titanium nitride layer.

### DETAILED DESCRIPTION OF THE PREFERRED EMBODIMENT

Apparatus

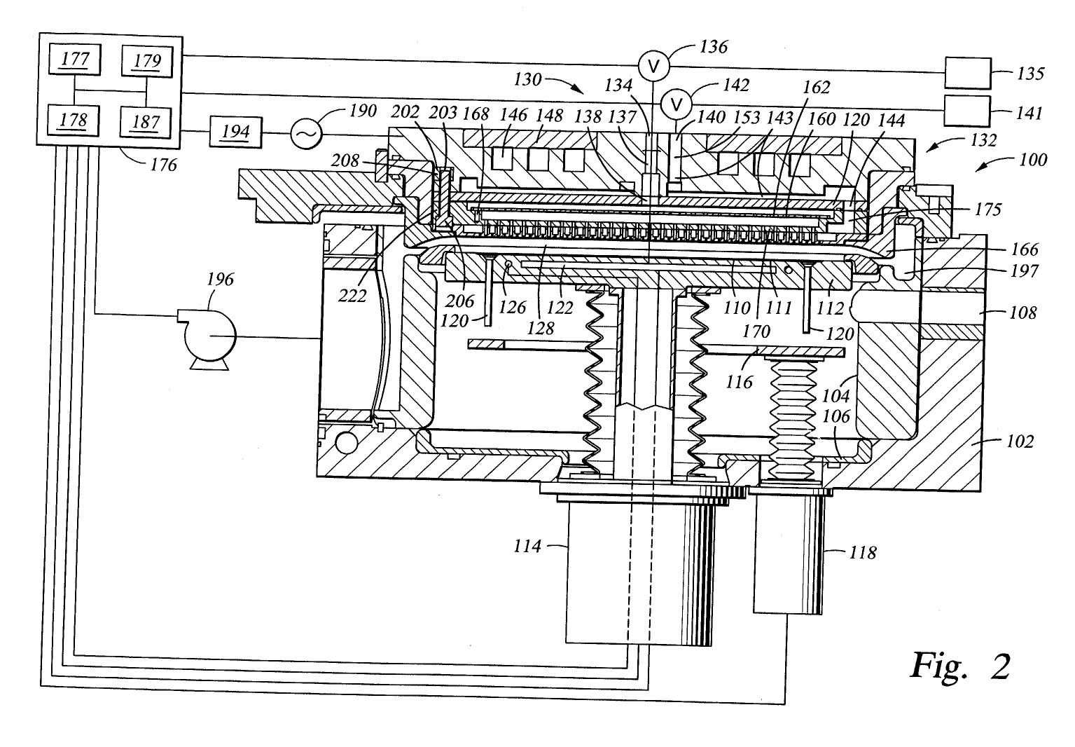

FIG. 2 is a schematic cross-sectional view of one embodiment of a chamber 100 adapted to deliver two separate gas flows to a processing region. The chamber 100 comprises a chamber body 102 having sidewalls 104 and a bottom 106. A liner, such as a quartz line, may line the sidewalls 104 and the bottom 106 of the chamber body 102 to provide thermal and/or electrical insulation. An opening 108 in the chamber 100 provides access for a robot (not shown) to deliver and retrieve substrates 110, such as, for example, 200 mm semiconductor wafers, 300 mm semiconductor wafers, or glass substrates, to the chamber 100.

A substrate support 112 supports the substrate 110 in the chamber 100 on a substrate receiving surface 111. The substrate support 112 is mounted to a lift motor 114 to raise and lower the substrate support 112 and a substrate 110 disposed thereon. A lift plate 116 connected to a lift motor 118 is mounted in the chamber and raises and lowers pins 120 movably disposed through the substrate support 112. The pins 120 raise and lower the substrate 110 over the surface of the substrate support 112.

The substrate support 112 may be heated to heat the substrate 110 disposed thereon. For example, the substrate support 112 may have an embedded heating element 122 to resistively heat the substrate support 112 by applying an electric current from a power supply (not shown). A temperature sensor 126, such as a thermocouple, may be embedded in the substrate support 112 to monitor the temperature of the substrate support 112. For example, a measured temperature may be used in a feedback loop to control electric current applied to the heating element 122 from a power supply (not shown), such that the substrate temperature can be maintained or controlled at a desired temperature or within a desired temperature range. Alternatively, the substrate 110 may be heated using radiant heat, such as by lamps.

A gas distribution system 130 is disposed at an upper portion of the chamber body 102 to provide two gas flows distributed in a substantially uniform manner over a substrate 110 disposed on the substrate receiving surface 111 in which the two gas flows are delivered in separate discrete paths through the gas distribution system 130. In the embodiment shown, the gas distribution system 130 comprises a gas box 132, a blocker plate 160 positioned below the gas box 132, and a showerhead 170 positioned below the blocker plate 160. The gas distribution system 130 provides two gas flows through two discrete paths to a processing region 128 defined between the showerhead 170 and the substrate support 112.

The gas box 132 as used herein is defined as a gas manifold coupling gas sources to the chamber. The gas box 132 comprises a first gas channel 137 and a second gas channel 143 providing two separate paths for the flow of gases through the gas box 132. The first gas channel 137 comprises a first gas input 134 and a first gas outlet 138. The first gas input is adapted to receive a first gas from a first gas source 135 through valve 136. The first gas outlet 138 is adapted to deliver the first gas to the top of the blocker plate 160. The second gas channel 143 of the gas box 132 comprises a second gas input 140 and a second gas outlet 144. The second gas input 140 is adapted to receive a second gas from a second gas source 141 through valve 142. The second gas outlet 144 is adapted to deliver the second gas to top of the showerhead 170. The term “gas” as used herein is intended to mean a single gas or a gas mixture. The valves 136, 142 control delivery of the first gas and the second gas into the first gas input 134 and the second gas input 140 respectively. Gas sources 135, 141 may be adapted to store a gas or liquid precursor in a cooled, heated, or maintained at ambient environment. The gas lines fluidly coupling the gas sources 135, 141 to the gas inputs 134, 140 may also be heated, cooled, or at ambient temperature.

The gas box 132 may further comprise one or more temperature fluid control channels 146 to control the temperature of the gas distribution system 130 by providing a cooling fluid or a heating fluid to the gas box 132 depending on the particular process being performed in the chamber 100. Controlling the temperature of the gas distribution system 130 may be used to prevent gas decomposition, deposition, or condensation within the gas distribution system 130.

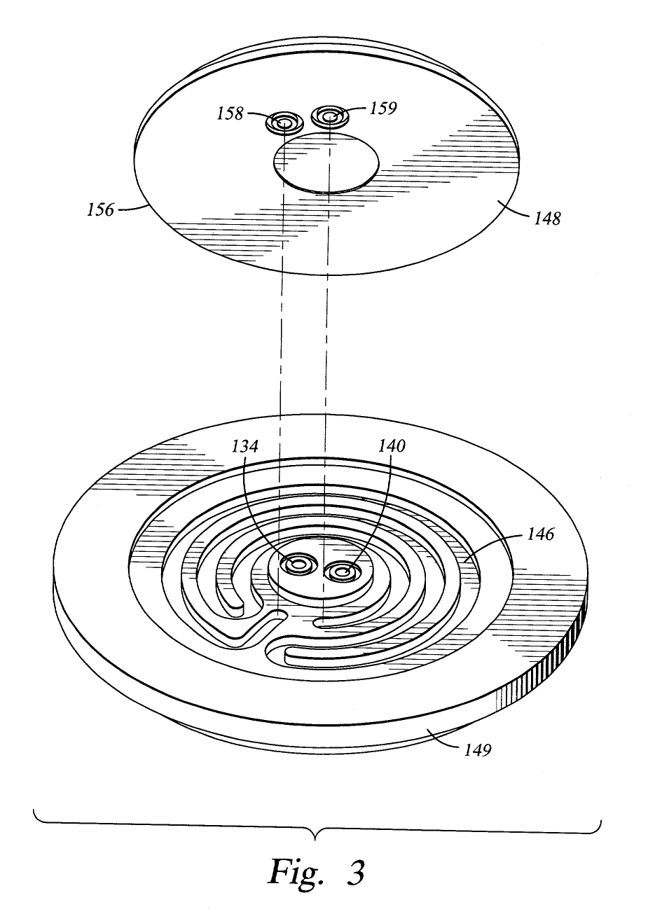

In the embodiment shown, the gas box 132 comprises a top plate 148, a center plate 149, and a bottom plate 150. FIG. 3 is an exploded top perspective view of the top plate 148 and the center plate 149 of the gas box 132 of FIG. 2. The top plate 148 provides the upper enclosure for the temperature fluid control channel 146. The top plate 148 has a fluid input 158 and fluid output 159 to circulate fluid through the temperature fluid control channel 146. The first gas input 134 and the second gas input 140 are disposed on the center plate 149 and are exposed through an aperture 156 in the top plate 148.

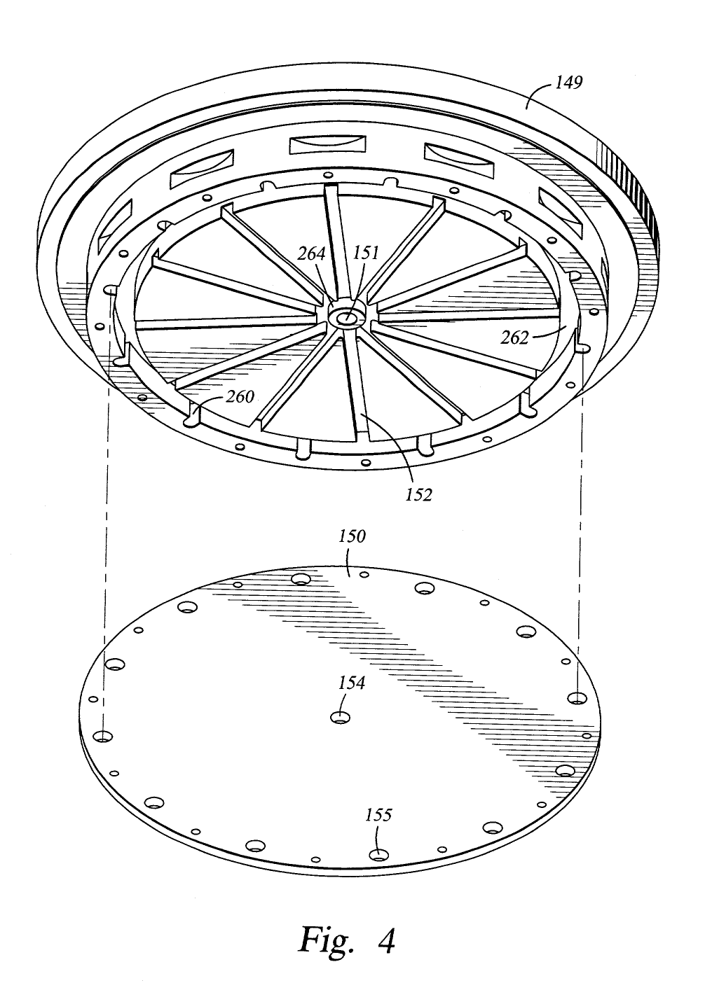

FIG. 4 is an exploded bottom perspective view of the center plate 149 and the bottom plate 150 of the gas box 132 of FIG. 2. In the embodiment shown, on the lower surface of the center plate 149, the first gas channel 137 (FIG. 2) comprises a tubular passageway 151. The second gas channel 143 (FIG. 2) comprises a tubular passageway 153 (FIG. 2) in fluid communication with an inner annular groove 264 in fluid communication with a plurality of laterally extending grooves 152 in fluid communication with an outer annular groove 262 having notches 260 disposed therearound. In one specific embodiment, the notches 260 are disposed along the outer annular groove 262 spaced from the laterally extending grooves 152. On the bottom plate 150, the first outlet 138 (FIG. 2) comprises a delivery hole 154 in communication with the tubular passageway 151. The second outlet 144 (FIG. 2) comprises a plurality of delivery holes 155 in communication with the notches 260 of the outer annular groove 262. The inner annular groove 262, the laterally extending grooves 152, and the outer annular groove 260 provide an interconnected passageway to deliver a substantially uniform flow of a gas from the delivery holes 155. In one specific embodiment, the center plate 149 and the bottom plate 150 may be brazed together to help prevent leaking between the first gas channel 137 (FIG. 2) and the second gas channel 144 (FIG. 2).

Referring to FIG. 2, the blocker plate 160 has a plurality of holes 162 to accommodate a gas flow therethrough from the first gas outlet 138 of the gas box 132 to the showerhead 170. The blocker plate 160 disperses the gas flow to the showerhead 170. In one specific embodiment, the diameter of holes 162 of the blocker plate 160 are between about 50 mils and about 100 mils. In one specific embodiment, the spacing between the blocker plate 160 and the gas box 132 is between about 100 mils and about 200 mils.

Referring to FIG. 2, the showerhead 170 comprises a first passageway to deliver a first gas from the blocker plate 160 to the processing region 128 between the showerhead 170 and the substrate support 112. The showerhead 170 further comprises a second passageway to delivery a second gas from the second outlet 144 of the gas box 132 to the processing region 128. In the embodiment shown, the showerhead 170 comprises a first plate 172 connected to a second plate 180.

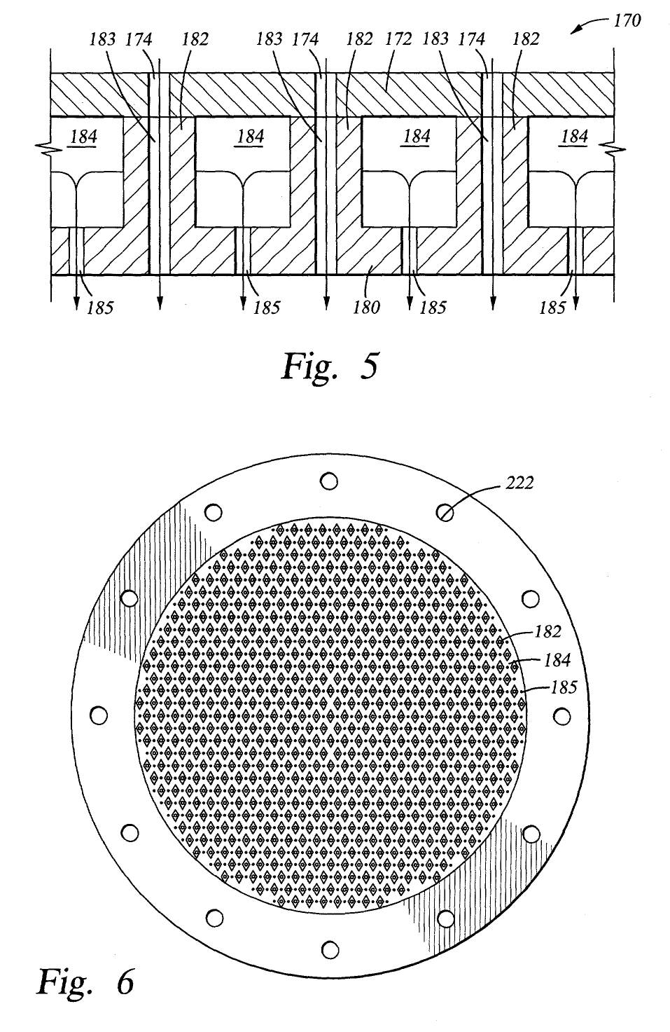

FIG. 5 is a schematic cross-sectional view of the showerhead 170 of FIG. 2. In the embodiment shown, the first plate 172 has a plurality of holes 174 to provide a flow of a gas therethrough. The second plate 180 comprises a plurality of columns 182 having column holes 183 formed therethrough and a plurality of interconnected grooves 184 having groove holes 185 formed therethrough. The top surface of the columns 182 are connected to the bottom surface of the first plate 172 so that the column holes 183 align with the holes 174 of the first plate 172. Therefore, the first passageway is provided through the holes 174 of the first plate 172 and through the column holes 183 of the columns 182 of the second plate 180. The first plate 172 further comprises delivery holes 175 (FIG. 2) in communication with the second gas outlet 144 (FIG. 2) of the gas box 132 and in communication with the grooves 184 of the showerhead 170. Therefore, the second passageway is provided through the delivery holes 175, through the interconnected grooves 184, and through the groove holes 185. In one embodiment, the first plate 172 and the second plate 180 are brazed together to prevent leaking between the first passageway and the second passageway. In one specific embodiment, the column holes 183 and the groove holes 185 of the showerhead 170 have a diameter between about 10 mils and about 250 mils, preferably between about 10 mils and about 60 mils In one specific embodiment, the diameter of the column holes 183 and the groove holes 185 are between about 10 mils and about 20 mils to provide more uniform gas flows to the surface of a substrate. The columns holes 183 and the groove holes 185 may also comprise tapered holes or holes having varying diameters from the top of the hole to the bottom of the hole. In one specific embodiment, the thickness of the showerhead 170 is about 500 mils or less, such as between about 500 mils and about 100 mils. In one specific embodiment, the spacing between the blocker plate 160 and the showerhead 170 is between about 200 mils and 300 mils.

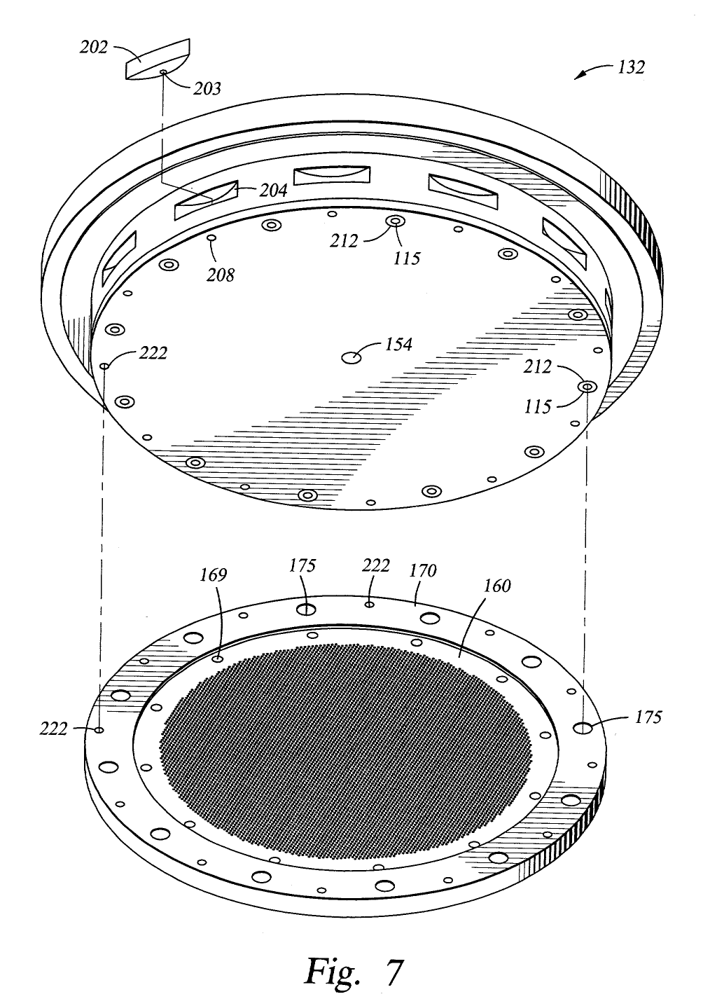

FIG. 6 is a top schematic view of the second plate 180 of the showerhead 170 of FIG. 2. In one embodiment, the columns 182 and grooves 184 are formed by machining the grooves 184 into the second plate 180. In the embodiment shown, the columns 182 are shaped as diamonds. The columns 182 may be other shapes, such as rounded shapes (i.e. oval or circular shapes). Other embodiments of the showerhead include a first piece having grooves and columns and a second piece comprising a plurality of holes.

Referring to FIG. 2, the showerhead 170 may be disposed on an upper portion of the chamber body 102, such as on a lid rim 166 disposed on the sidewalls 104 of the chamber body 102. The lid rim 166 may comprise an insulating material to electrically insulate the showerhead 170 from the chamber body 102. The insulating material may be a ceramic, a polymer, or other materials. The spacing between the showerhead 170 and the substrate receiving surface 111 in a process position may be adjusted depending on the particular process being performed, such as between about 200 mils and about 1,000 mils, preferably between about 300 mils and about 500 mils.

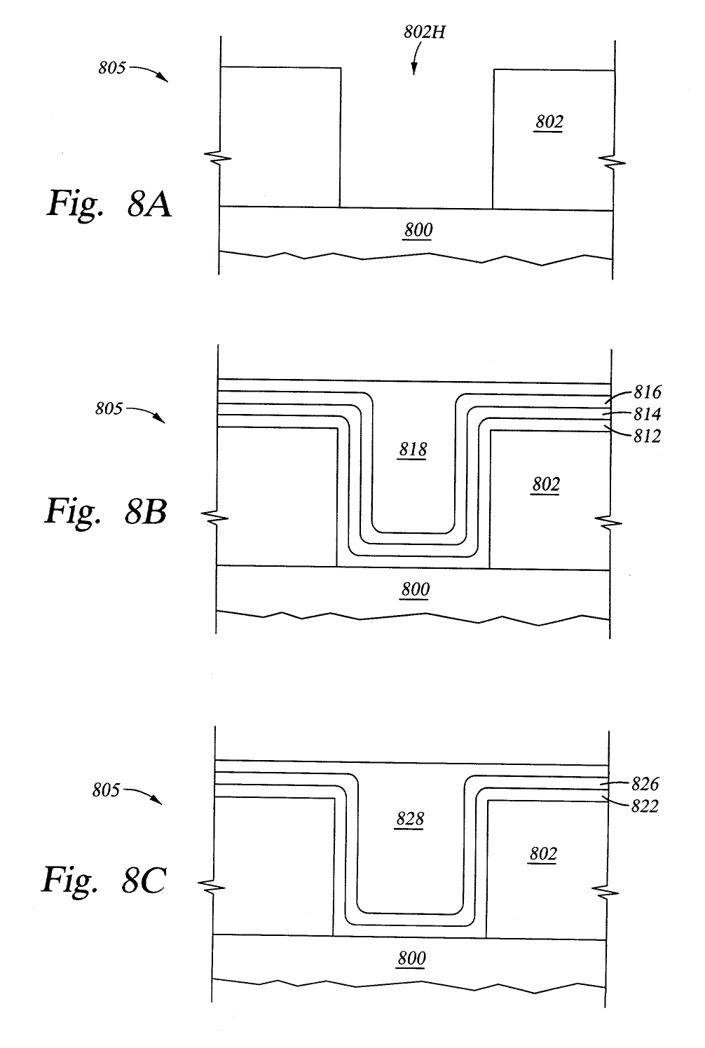

FIG. 7 is an exploded perspective view of the gas box 132 and the showerhead 170. The blocker plate 160 is mounted to the showerhead 170 by a plurality of screws 168 (one is shown in the FIG. 2) disposed through mounting holes 169 of the blocker plate 160. The showerhead 170 is in turn coupled to the gas box 132 using a plurality of inserts 202 (one is shown in FIG. 2) disposed in slots 204 formed in side portions of the gas box 132. Inserts as used herein is defined as any component, removable or fixed to the gas box 132, used to provide a body for receiving one or more screws. A plurality of screws 206 (one shown in FIG. 2) are disposed through mounting holes 222 of the showerhead 170, disposed through mounting holes 208 of the gas box 132, and threadingly disposed in holes 203 of inserts 202. The holes 203 of the inserts may be pre-threaded or may be threaded during insertion of the screws. O-rings 212 may be positioned around the delivery holes 155 to prevent leaking between the gas box 132 and the showerhead 170. Other embodiments of the gas distribution system 130 include the components connected together in other arrangements and with other connection devices.

The components of the gas distribution system 130 may be made of stainless steel, aluminum, nickel-plated metal, nickel-plated aluminum, nickel, nickel alloys (such as INCONEL®, HASTELLOY®), other suitable materials, and combinations thereof. The blocker plate 160, the showerhead 170, inserts 202, screws 206, and screws 168 preferably comprise solid nickel to provide corrosion resistance from the processing gas and/or plasma species. The gas box 132 preferably comprises a nickel-plated metal, such as nickel-plated aluminum, to provide the corrosion resistance of nickel at a lower price than solid nickel.

In one aspect, mounting the showerhead 170 to the gas box 132 with the use of screws 206 through the inserts 202 is preferred over directly using screws 206 inserted into the gas box 132. For example, the holes of a nickel plated gas box for receipt of screws may easily corrode due to the wearing away of the nickel plated surface of the holes from the contact of the screws and holes. In comparison, solid nickel inserts 202 permit the use of a nickel plated gas box 132 since the screws 206 will be threadingly coupled with the inserts 202 rather than the gas box 132.

Referring to FIG. 2, a power source 190 may be electrically coupled to the showerhead 170 (i.e. to the gas box 132 or directly to the showerhead 170). The power source 190 may be a RF or DC power source. The power source 190 may be coupled to a matching network 194 to control delivery of power to the power source 190. With a grounded substrate support 112, the showerhead 170 serves as a power electrode and the substrate support 112 serves as a ground electrode to generate a plasma from the gases introduced therebetween. In another embodiment, a power source may be coupled to the substrate support and the showerhead may be grounded to serve as spaced apart electrodes for generating a plasma.

A vacuum system 196 is in communication with a pumping channel 197 formed in the chamber body 102 to evacuate gases from the chamber 100 and to help maintain a desired pressure or a desired pressure range inside the chamber 100.

Control unit 176 may be coupled to the chamber 100 to control processing conditions. For example, the control unit 176 may be connected to the valves 136, 142 to control the flow of gases through the gas distribution system 130 during different stages of a substrate process sequence. In another example, the control unit 176 may be connected to the matching network 194 to control the power supplied to the showerhead 170 to control generation of a plasma between the showerhead 170 and the substrate support 112. In another example, the control unit 176 may be connected to the embedded heating element 122 to control the temperature of the substrate support 112. The control unit 176 may be configured to be responsible for automated control of other activities used in substrate processing, such as substrate transport, chamber evacuation, and other activities, some of which are described elsewhere herein.

Illustratively, control unit 176 may be one of any form of general purpose computer process that can be used in an industrial setting for controlling various chambers and sub-processors. For example, the control unit 176 may comprise a programmed personal computer, work station computer, and the like and may include a central processing unit 177, support circuitry 178, and memory 179 containing associated control software 187. Memory 179 may be any suitable memory, such as random access memory, read only memory, floppy disk drive, hard disk, or any other form of digital storage, local or remote. Bi-directional communications between control unit 176 and various other components of the chamber 100 are handled through numerous signal cables collectively referred to as signal buses 188, some of which are illustrated in FIG. 2.

In operation, a substrate 110 is delivered to the chamber 100 through the opening 108 by a robot (not shown). The substrate 110 is positioned on the substrate support 112 through cooperation of the lift pins 120 and the robot. The substrate support 112 raises the substrate 110 into close opposition to the showerhead 170. A first gas and/or a second gas is injected into the chamber 100 through the first gas inlet 134 and/or the second gas inlet 140 of the gas box 132. If a first gas is injected, the first gas flows though the first gas channel 137 of the gas box 132 to the blocker plate 160, through the holes 162 of the blocker plate 160 to the showerhead 170, and through the column holes 183 of the columns 182 of the showerhead 170 to the processing region 128 defined between the showerhead 170 and the substrate support 112. If a second gas is injected, the second gas flows through the second gas channel 143 of the gas box 132 to the delivery holes 175 of the showerhead 170, through the grooves 184 and groove holes 185 of the showerhead 170 to the processing region 128 defined between the showerhead 170 and the substrate support 112. Excess gas, by-products, etc. flow into the pumping channel 197 and are then exhausted from the chamber by a vacuum system 196.

In one aspect, a plasma may be generated between the showerhead 170 and the substrate support 112 from gases, whether a first gas and/or a second gas, introduced by the showerhead 170. In one aspect, if a first gas and/or a second gas is introduced alone by the showerhead 170, the showerhead 170 provides a substantially uniform flow of the gas or gas mixture to the processing region 128 between the showerhead and the substrate support 112 which is advantageous in a thermal chemical vapor deposition process, a plasma enhanced chemical vapor deposition process, a plasma treatment, or other processing technique performed by the chamber.

Process

Chamber 100 as described above in reference to FIGS. 2-7 may be used to implement the following exemplary processes. Chamber 100 may also be used to implement other processes. It should also be understood that the following processes may be performed in other chambers as well.

A. Formation of a Titanium Laver

Chamber 100 may be used to deposit a titanium layer by plasma-enhanced chemical vapor deposition. Plasma-enhanced chemical vapor deposition of a titanium layer comprises introducing a titanium-containing compound, such as titanium tetrachloride (TiCl₄), and introducing a hydrogen-containing compound, such as hydrogen gas (H₂), through the showerhead 170 to the processing region 128. Other titanium-containing compounds which may also be used include, but are not limited to, other titanium halides, such as titanium iodide (Til₄) and titanium bromide (TiBr₄), and metal organic compounds, such as tetrakis(dimethylamido)titanium (TDMAT), tetrakis(diethylamido) titanium (TDEAT), among others, and combinations thereof. Other hydrogen-containing compounds which may also be used include, but are not limited to, silane (SiH₄), borane (BH₃), diborane (B₂H₆), triborane (B₃H₉), etc, and combinations thereof. The titanium-containing compound and the hydrogen-containing compound may be provided with dilutant gases or carrier gases, such as argon (Ar), helium (He), and combinations thereof.

In one embodiment, the titanium-containing compound and the hydrogen-containing compound are introduced separately through the showerhead 170 to the processing region 128 to reduce the likelihood of reaction of the two compounds within the showerhead 170 and the formation of particles within the showerhead 170. For example, the titanium-containing compound may be introduced through the column holes 183 of the showerhead 170 and the hydrogen-containing compound may be introduced through the groove holes 185 of the showerhead 170 to the processing region 128. In another example, titanium-containing compound may be introduced through the groove holes 185 of the showerhead and the hydrogen-containing compound may be introduced through the column holes 183 of the showerhead 170. Nonetheless, the titanium-containing compound and the hydrogen-containing compound may alternatively be introduced together through the showerhead 170.

One exemplary process regime for depositing a titanium layer by plasma-enhanced chemical vapor deposition comprises providing titanium tetrachloride at a flow rate of about 50 mg/min and providing hydrogen gas at a flow rate of about 2,000 sccm to about 4,000 sccm through the showerhead 170. An RF power density between about 1 watt/cm² and about 3 watts/cm² may be provided by the power source 190 to provide a plasma from the gas mixture between the showerhead 170 and the substrate support 112. The substrate may be heated to a substrate temperature between about 400° C. to about 700° C. at a chamber pressure between about 5 torr and about 30 torr. The above deposition parameters provide a deposition rate for titanium between about 1 Å/sec and about 3 Å/sec.

B. Nitrogen Plasma Treatment of a Titanium Laver

Chamber 100 may be used to perform a nitrogen plasma treatment of a titanium layer, such as a titanium layer formed as described above. A nitrogen plasma treatment of a titanium layer comprises introducing a nitrogen-containing compound, such as ammonia (NH₃), through the showerhead 170. Preferably, deposition of a titanium layer and plasma treatment of the titanium layer are performed in a single chamber. When deposition of a titanium layer and plasma treatment of the titanium layer are performed in the same chamber, the nitrogen-containing compound used during the plasma treatment is preferably introduced through the showerhead 170 separately from the titanium-containing compound used during deposition of the titanium layer to reduce the likelihood of the two compounds reacting within the showerhead 170 and forming particles. For example, the titanium-containing compound may be introduced through the column holes 183 of the showerhead 170 to the processing region 128 during deposition of a titanium layer and the nitrogen-containing compound may be introduced through the groove holes 185 of the showerhead 170 to the processing region 128 during the plasma treatment. In another example, the titanium-containing compound may be introduced through the groove holes 185 of the showerhead 170 to the processing region 128 and the nitrogen-containing compound may be introduced through the column holes 183 of the showerhead 170 to the processing region 128. Other examples of nitrogen-containing compounds which may be used include nitrogen gas (N₂) along with a hydrogen gas (H₂), hydrazine (N₂H₄), among others, and combinations thereof. Dilutant gases or carrier gases, such as argon (Ar), helium (He), and combinations thereof may be added to the nitrogen-containing compound.

One exemplary process regime for plasma treating a titanium layer comprises providing ammonia. An RF power density between about 0.5 watts/cm² and about 10 watts/cm² may be provided by the power source 190 to provide a plasma from the gas mixture between the showerhead 170 and the substrate support 112. The substrate may be heated to a substrate temperature between about 400° C. to about 700° C. at a chamber pressure between about 5 torr and about 30 torr. The titanium film may be plasma treated for a time period between about 5 seconds and about 60 seconds. It is believed that the plasma treatment coverts a top surface of the titanium layer to titanium nitride.

i. Capping Laver

The plasma treatment may be used to form an optional capping layer or a passivation layer by converting a top surface of the titanium layer to titanium nitride. It is believed that the capping layer or passivation layer protects the titanium layer from reacting with oxygen and other gases which the titanium layer may be exposed to between process steps. In general, if a titanium layer and another layer is deposited over the titanium layer in separate chambers, a capping layer is desirable.

ii. Composite Titanium/Titanium Nitride Layer

The plasma treatment may be used to form a composite titanium/titanium nitride layer. The composite titanium/titanium nitride layer is formed by the alternating deposition of a titanium layer and plasma treatment of the titanium layer. For example, a titanium layer is deposited to a thickness of less than about 100 Å, such as by the methods described above. Then, the titanium layer is plasma treated to convert at least a portion of the titanium layer to titanium nitride, such as by the methods described above. Another titanium layer may be formed thereon and then plasma treated. The alternating deposition/plasma treatment steps may be performed until a desired thickness of a composite titanium/titanium nitride layer is achieved. The composite titanium/titanium nitride layer when formed on silicon dioxide (SiO₂) has a resistivity of less than about 70 μΩ-cm, which is about 3 times smaller than the resistivity of titanium films obtained using standard CVD processes (typically about 200 μΩ-cm). Additionally, the composite titanium/titanium nitride layer has better sheet resistance uniformity across the deposited film.

C. Titanium Nitride Formation

Chamber 100 may be used to form a titanium nitride layer by chemical vapor deposition. Chemical vapor deposition of a titanium nitride film comprises introducing a titanium containing compound, such as titanium tetrachloride (TiCl₄), and a nitrogen containing compound, such as ammonia (NH₃), separately through the showerhead 170 to the processing region 128 to reduce the likelihood of the two compounds reacting within the showerhead 170 and forming particles. For example, the titanium-containing compound may be introduced through the column holes 183 of the showerhead 170 to the processing region 128 and the nitrogen-containing compound may be introduced through the groove holes 185 of the showerhead 170 to the processing region 128. In another example, the titanium-containing compound may be introduced through the groove holes 185 of the showerhead 170 to the processing region 128 and the nitrogen-containing compound may be introduced through the column holes 183 of the showerhead 170 to the processing region 128. Other titanium-containing compounds which may also be used include, but are not limited to, other titanium halides, such as titanium iodide (Til₄) and titanium bromide (TiBr₄), and metal organic compounds, such as tetrakis(dimethylamido)titanium (TDMAT), tetrakis(diethylamido) titanium (TDEAT), among others, and combinations thereof. Other examples of nitrogen-containing compounds which may be used include hydrazine (N₂H₄), among others, and combinations thereof. Helium gas (He), argon gas (Ar), nitrogen gas (N₂) or other inert gases, may also be used, either singly or in combination (i.e., as a gas mixture) within either the titanium containing compound and the nitrogen containing compound

One exemplary process regime for depositing a titanium nitride layer by chemical vapor deposition comprises providing titanium tetrachloride, along with nitrogen gas, at a flow rate between about 50 mg/min and about 350 mg/min and ammonia, along with nitrogen gas, at a flow rate between about 100 sccm and about 500 sccm. The substrate may be heated to a substrate temperature between about 400° C. to about 700° C. at a chamber pressure between about 5 torr and about 30 torr. The above deposition parameters provide a deposition rate for the titanium nitride of about 5 Å/sec to about 13 Å/sec by a thermal chemical vapor deposition process. In other embodiments, the titanium nitride layer may be deposited by utilizing plasma-enhanced chemical vapor deposition.

D. Plasma Treatment of the Titanium Nitride Layer

Chamber 100 may be used to perform a nitrogen plasma treatment of a titanium nitride layer, such as a titanium nitride layer formed as described above. A nitrogen plasma treatment of a titanium nitride layer comprises introducing a nitrogen-containing gas, such as ammonia (NH₃), through the showerhead 170. Preferably, deposition of a titanium layer and plasma treatment of the titanium layer are performed in a single chamber. When deposition of a titanium nitride layer and plasma treatment of the titanium nitride layer are performed in the same chamber, the nitrogen-containing gas is preferably introduced through the showerhead 170 separately from the titanium-containing gas used during deposition of the titanium nitride layer to reduce the likelihood of the two compounds reacting within the showerhead 170 and forming of particles. For example, the titanium-containing compound may be introduced through the column holes 183 of the showerhead 170 to the processing region 128 during deposition of a titanium nitride layer and the nitrogen-containing gas may be introduced through the groove holes 185 of the showerhead 170 to the processing region 128 during the plasma treatment. In another example, the titanium-containing compound may be introduced through the groove holes 185 of the showerhead 170 to the processing region 128 and the nitrogen-containing compound may be introduced through the column holes 183 of the showerhead 170 to the processing region 128. Other examples of a nitrogen-containing gas which may be used include a nitrogen gas (N₂) along with a hydrogen gas (H₂), hydrazine (N₂H₄), among others, and combinations thereof. Dilutant gases or carrier gas, such as argon (Ar), helium (He), and combinations thereof may be added to the nitrogen-containing gas.

One exemplary process regime for plasma treating a titanium nitride layer comprises providing ammonia. An RF power density between about 0.5 watts/cm² and about 10 watts/cm² may be provided by the power source 190 to provide a plasma from the gas mixture between the showerhead 170 and the substrate support 112. The substrate may be heated to a substrate temperature between about 400° C. to about 700° C. at a chamber pressure between about 5 torr and about 30 torr. The titanium nitride layer may be plasma treated for a time period between about 5 seconds and about 60 seconds.

A titanium nitride layer having a thickness of about 300 Å, plasma treated by the methods as described above, has a resistivity of less than about 180 μΩΩ-cm and a sheet resistance uniformity of less than about 5% as compared to a resistivity of greater than about 7,200 μΩ-cm and a sheet resistance uniformity of about greater than about 5% for a non-plasma treated titanium nitride layer. A titanium nitride layer having a thickness of about 300 Å, plasma treated by the methods as described above, has reduced stress. A plasma treated titanium nitride layer has a compressive stress of about-1−3×10⁹ dynes/cm² in comparison to a non-plasma treated titanium layer which typically has a tensile stress of about 3−8×10⁹ dynes/cm².

One or more titanium nitride layer may be deposited in which each titanium nitride layer is plasma treated to form a combined titanium nitride layer. Thus, alternating deposition of a titanium nitride and plasma treatment thereof may be performed until a desired titanium nitride layer thickness is achieved.

Applications

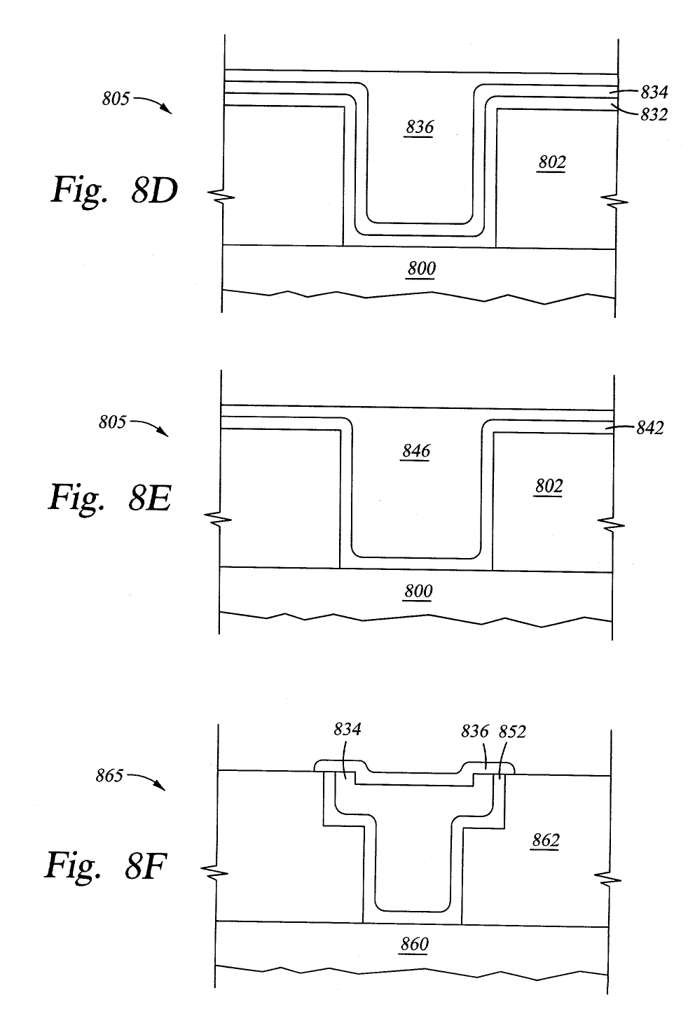

FIGS. 8A-F are cross-sectional views of a substrate illustrating various exemplary embodiments of applications of a titanium and/or a titanium nitride layer. Thicknesses of the layers are variable and depend on the size of the structure to be fabricated. Thicknesses of the layers described herein illustrate exemplary thicknesses. FIG. 8A is a structure 805 at one stage in the formation of an interconnect structure. The structure 805 comprises a substrate 800 having a dielectric layer 802 comprising a dielectric material, such as silicon dioxide, fluorosilicate glass (FSG), undoped silicate glass (USG), organosilicates, silicon carbide, or other suitable materials. The substrate 800 refers to any workpiece upon which film processing is performed, such as a semiconductor substrate, a glass substrate, or a material layer formed over a semiconductor substrate or glass substrate. The dielectric layer 802 is patterned and etched to provide an aperture 802H.

FIG. 8B is one embodiment of an application of a titanium layer and a titanium nitride layer, formed by the methods as described above, utilized as a barrier layer for metallization, such as in the formation of a tungsten plug. A titanium layer 812 is formed over the structure 805 of FIG. 8A by plasma-enhanced chemical vapor deposition. In one specific embodiment, the titanium layer 812 is deposited to a thickness between about 50 Å and about 300 Å. The titanium layer 812 may be optionally treated by a nitrogen plasma treatment to form a passivation layer 814. In one specific embodiment, the passivation layer is formed to a thickness of about 50 Å or less. A titanium nitride layer 816 may be formed over the passivation layer 814 by thermal chemical vapor deposition. In one specific embodiment, the titanium nitride layer 816 is formed to a thickness between about 50 Å and about 300 Å. A tungsten layer 818 may be formed over the titanium nitride layer 816, by methods well-known to one skilled in the art, to form a metal plug.

FIG. 8C is one embodiment of an application of a composite titanium/titanium nitride layer, formed by the methods as described above, as used as a barrier layer for metallization, such as in the formation of a tungsten plug. A titanium/titanium composite layer 822 is formed over the structure 805 of FIG. 8A by alternating plasma-enhanced chemical vapor deposition of a titanium layer and nitrogen plasma treatment thereof. In one specific embodiment, the composite titanium/titanium nitride layer 822 is deposited to a thickness between about 50 Å and about 300 Å. A titanium nitride layer 826 may be formed over the composite titanium/titanium nitride layer 822 by thermal chemical vapor deposition. In one specific embodiment, the titanium nitride layer is formed to a thickness between about 50 Å and about 300 Å. A tungsten layer 828 may be formed over the titanium nitride layer 826, by methods well-known to one skilled in the art, to form a metal plug.

FIG. 8D is one embodiment of an application of a titanium layer and a titanium nitride layer, formed by the methods as described above, utilized as a titanium nitride plug. A titanium layer 832 is formed over the structure 805 of FIG. 8A by plasma-enhanced chemical vapor deposition. In one specific embodiment, the titanium layer 832 is deposited to a thickness between about 50 Å and about 300 Å. The titanium layer 832 may be optionally treated by a nitrogen plasma treatment to form a passivation layer 834. A titanium nitride layer 836 may be formed over the passivation layer by thermal chemical vapor deposition. In one specific embodiment, the titanium nitride layer 836 is formed to a thickness between about 500 Å and about 1,500 Å. The titanium nitride layer 836 may be optionally treated by a nitrogen plasma treatment.

FIG. 8E is another embodiment of an application of a titanium layer and a titanium nitride layer, formed by the methods as described above, utilized as a titanium nitride plug. A titanium/titanium composite layer 842 is formed over the structure 805 of FIG. 8A by alternating plasma-enhanced chemical vapor deposition of a titanium layer and nitrogen plasma treatment thereof. In one specific embodiment, the composite titanium/titanium nitride layer 842 is deposited to a thickness between about 50 Å and about 300 Å. A titanium nitride layer 846 may be formed over the composite titanium/titanium nitride layer 842 by thermal chemical vapor deposition. In one specific embodiment, the titanium nitride layer 846 is formed to a thickness between about 500 Å and about 1,500 Å. The titanium nitride layer 846 may be optionally treated by a nitrogen plasma treatment. Other applications of the titanium and titanium nitride layer formed by the methods as described above are also include in the present invention.

FIG. 8F is another embodiment of an application of a titanium nitride layer, formed by the methods as described above, utilized as an electrode in a capacitor structure. FIG. 8F is a structure 865 at one stage in the formation of an interconnect structure. The structure 865 comprises a substrate 860 having a dielectric layer 862 comprising a dielectric material, such as silicon dioxide, fluorosilicate glass (FSG), undoped silicate glass (USG), organosilicates, silicon carbide, or other suitable materials. The substrate 860 refers to any workpiece upon which film processing is performed, such as a semiconductor substrate, a glass substrate, or a material layer formed over a semiconductor substrate or glass substrate. The dielectric layer 862 is patterned and etched to provide an aperture. A titanium nitride layer 852 is deposited over the structure 865 by thermal chemical vapor deposition to serve as a bottom electrode. In one specific embodiment, the titanium nitride layer 852 is deposited to a thickness between about 500 Å and about 1,500 Å. The titanium nitride layer 852 may be optionally treated with a nitrogen plasma treatment. A dielectric layer 854, such as a tantalum pentoxide (Ta₂O₅) may be deposited over the titanium nitride layer 852 by methods well-known to one skilled in the art. The dielectric layer 854 may be patterned, etched, and planarized. A titanium nitride layer 856 is then deposited over the dielectric layer 854 to serve as a top electrode. In one specific embodiment, the titanium nitride layer 852 is deposited to a thickness between about1000 Å and about 300 Å, although other thicknesses may be used. The titanium nitride layer 852 may be optionally treated with a nitrogen plasma treatment.

Chamber 100, as described in FIGS. 2-7, may be used to advantage in the formation of a titanium layer and a titanium nitride layer in the applications as shown in FIGS. 8B-8F. In one aspect, because chamber 100 is adapted to provide two separate gas flows through the showerhead 170 into the processing region 128, chamber 100 may be used to advantage in delivering two reactive gases separately in one process or for a plurality of processes without the two reactive gases reacting and forming particles within the showerhead. As a consequence, chamber 100 allows a user much flexibility in processing substrates.

For instance, a single chamber 100 may be adapted to perform two or more specific processes from the group including forming a titanium layer by plasma enhanced chemical vapor deposition, forming a passivation layer by a nitrogen plasma treatment of a titanium layer, forming a composite titanium/titanium nitride layer by an alternating plasma enhanced chemical vapor deposition and a nitrogen plasma treatment, forming a titanium nitride layer by thermal chemical vapor deposition, and plasma treating a titanium nitride layer. For example, a single chamber may be used to form a titanium layer by plasma-enhanced chemical vapor position and to form a passivation layer by a nitrogen plasma treatment. In another example, a single chamber may be used to form a titanium nitride layer by chemical vapor deposition and to plasma treat the titanium nitride layer. In still another example, a single chamber may be used to form a titanium layer by plasma-enhanced chemical vapor deposition and to form a titanium nitride by chemical vapor deposition. In yet another example, a single chamber may be used to form a composite titanium/titanium nitride layer by alternating plasma-enhanced chemical vapor deposition and a nitrogen plasma treatment to form a titanium nitride layer by chemical vapor deposition. In one aspect, performing two or more processes in a single chamber may improve throughput through the system and reduce contamination of the substrate during transport of the substrate to other chambers.

Of course, a chamber 100 may be adapted to perform one specific process. For example, one chamber is adapted to deposit a titanium layer by plasma enhanced chemical vapor deposition, one chamber is adapted to form a passivation layer by a nitrogen plasma treatment of a titanium layer, one chamber is adapted to deposit a composite titanium/titanium nitride layer by an alternating plasma enhanced chemical vapor deposition and a nitrogen plasma treatment, one chamber is adapted to deposit a titanium nitride layer by thermal chemical vapor deposition, and one chamber is adapted to plasma treat a titanium nitride layer.

While foregoing is directed to the preferred embodiment of the present invention, other and further embodiments of the invention may be devised without departing from the basic scope thereof, and the scope thereof is determined by the claims that follow.

1. A gas delivery system, comprising:
a gas box comprising a first gas channel having a first outlet and a second gas channel having a second gas outlet;
a blocker plate disposed below the gas box, the blocker plate having a plurality of blocker plate holes;
a showerhead disposed below the blocker plate, the showerhead comprising columns having column holes in communication with a top surface and a bottom surface of the showerhead and interconnected grooves having groove holes in communication with the bottom surface of the showerhead;
the first outlet of the gas box adapted to supply a first gas through the blocker plate holes of the blocker plate to the column holes of the showerhead; and
the second gas outlet of the gas box being coupled to the showerhead and adapted to supply a second gas through the interconnect grooves of the showerhead to the groove holes of the showerhead.

2. The gas delivery system of claim 1, wherein the gas box further comprises a temperature fluid control channel.

3. The gas delivery system of claim 1, wherein the gas box further comprises slots formed on side portions of the gas box, the gas delivery system further comprising inserts positioned in the slots, the showerhead being coupled to the gas box with screws disposed through the showerhead and through the gas box and threadingly coupled to the inserts.

4. The gas delivery system of claim 3, wherein the inserts comprise nickel.

5. The gas delivery system of claim 3, wherein the blocker plate is coupled to the showerhead.

6. The gas delivery system of claim 1, wherein the gas box, blocker plate, and showerhead comprise a material selected from the group consisting of nickel, nickel alloys, nickel-plated metal, nickel-plated aluminum, aluminum, stainless steel, and combinations thereof.

7. The gas delivery system of claim 6, wherein the blocker plate and the showerhead comprise nickel.

8. The gas delivery system of claim 6, wherein the gas box comprises a nickel-plated metal.

9. The gas delivery system of claim 1, wherein the showerhead is formed by coupling two plates together.

10. The gas delivery system of claim 2, wherein the gas box is formed by coupling three plates together.

11. A substrate processing chamber, comprising:
a substrate support having a substrate receiving surface;
a showerhead disposed over the substrate receiving surface, the showerhead comprising a first passageway having a plurality of first passageway holes and a second passageway having a plurality of second passageway holes, the first passageway adapted to deliver a first gas flow through the first passageway holes to the substrate receiving surface and a second passageway adapted to deliver a second gas flow through the second passageway holes to the substrate receiving surface; and
a plasma power source.

12. The substrate processing chamber of claim 11, wherein the plasma power source is in electrical communication with the showerhead.

13. The substrate processing chamber of claim 11, wherein the plasma power source is in electrical communication with the substrate support.

14. The substrate processing chamber of claim 11, wherein the plasma power source is an RF power source.

15. The substrate processing chamber of claim 11, wherein the plasma power source selectively provides a plasma power to perform a plasma process and a non-plasma process.

16. The substrate processing chamber of claim 11, wherein the first passageway of the showerhead comprises column holes through columns and in communication with a top surface and a bottom surface of the showerhead and wherein the second passageway comprises interconnected grooves having groove holes in communication with a bottom surface of the showerhead.

17. The substrate processing chamber of claim 16, further comprising a gas box disposed over the showerhead, the gas box comprising a first gas channel having a first outlet and a second gas channel having a second gas outlet, the first outlet of the gas box adapted to supply a first gas to the column holes of the showerhead,
the second gas outlet of the gas box being adapted to supply a second gas through the interconnect grooves of the showerhead to the groove holes of the showerhead.

18. The substrate processing chamber of claim 17, wherein the gas box further comprises a temperature fluid control channel.

19. The substrate processing chamber of claim 17, further comprising a blocker plate having a plurality of blocker plate holes and disposed between the gas box and the showerhead, the first outlet of the gas box adapted to supply the first gas through the blocker plate holes of the blocker plate to the column holes of the showerhead.

20. The substrate processing chamber of claim 17, further comprising a first gas line in fluid communication with the first gas channel of the gas box and a second gas line in fluid communication with the second gas channel of the gas box.

21. The substrate processing chamber of claim 20, wherein the first gas line and the second gas line are heated.

22. The substrate processing chamber of claim 17, further comprising a titanium containing gas source and a nitrogen containing gas source fluidly coupled to opposite gas channels of the gas box.

23. The substrate processing chamber of claim 22, wherein the titanium containing gas source is fluidly coupled to the first gas channel of the gas box and the nitrogen containing gas source is fluidly coupled to the second gas channel of the gas box.

24. The substrate processing chamber of claim 22, wherein the titanium containing gas source comprises a titanium tetrachloride gas source and wherein the nitrogen containing gas source comprises an ammonia gas source.

25. The substrate processing chamber of claim 22, further comprising a hydrogen containing gas source fluidly coupled to the gas box.

26. The substrate processing chamber of claim 22, wherein the hydrogen containing gas source and the nitrogen containing gas source are fluidly coupled to the same gas channel.

27. The substrate processing chamber of claim 22, wherein the hydrogen containing gas source and the titanium containing gas source are fluidly coupled to the same gas channel.

28. A method of processing a substrate in a single chamber, comprising:
forming a titanium layer over a substrate structure by plasma enhanced chemical vapor deposition; and
capping the titanium layer by a nitrogen plasma treatment of the titanium layer.

29. The method of claim 28, wherein forming a titanium layer comprises providing a titanium containing gas through a first passageway of a showerhead and capping the titanium layer comprises providing a nitrogen containing gas through a second passageway of the showerhead.

30. The method of claim 29, wherein the first passageway comprises column holes and wherein the second passageway comprises groove holes.

31. The method of claim 29, wherein the titanium containing gas comprises titanium tetrachloride.

32. The method of claim 29, wherein the nitrogen containing gas comprises ammonia.

33. The method of claim 29, wherein forming a titanium layer further comprises providing a hydrogen containing gas.

34. The method of claim 33, wherein the hydrogen containing gas is provided through the second passageway of the showerhead.

35. A method of forming a composite titanium/titanium nitride layer over a substrate structure in a single chamber, comprising performing a plurality of process cycles, the process cycle comprising:
depositing a titanium layer by plasma enhanced chemical vapor deposition; and
treating the titanium layer with a nitrogen plasma treatment.

36. The method of claim 35, wherein depositing a titanium layer comprises providing a titanium containing gas through a first passageway of a showerhead and treating the titanium layer comprises providing a nitrogen containing gas through a second passageway of the showerhead.

37. The method of claim 36, wherein the first passageway comprises column holes and wherein the second passageway comprises groove holes.

38. The method of claim 36, wherein the titanium containing gas comprises titanium tetrachloride.

39. The method of claim 36, wherein the nitrogen containing gas comprises ammonia.

40. The method of claim 36, wherein depositing a titanium layer further comprises providing a hydrogen containing gas.

41. The method of claim 40, wherein the hydrogen containing gas is provided through the second passageway of the showerhead.

42. A method of processing a substrate in a single chamber, comprising:
forming a titanium nitride layer by chemical vapor deposition, and
treating the titanium nitride layer with a nitrogen plasma.

43. The method of claim 42, wherein forming a titanium nitride layer comprises providing a titanium containing gas through a first passageway of a showerhead and providing a nitrogen containing gas through a second passageway of the showerhead.

44. The method of claim 43, wherein treating the titanium layer comprises providing a nitrogen containing gas through the second passageway of the showerhead.

45. The method of claim 43, wherein the first passageway comprises column holes and wherein the second passageway comprises groove holes.

46. The method of claim 43, wherein the titanium containing gas comprises titanium tetrachloride.

47. The method of claim 43, wherein the nitrogen containing gas comprises ammonia.

48. A method of processing a substrate in a single chamber, comprising:
forming a titanium layer over a substrate structure by plasma enhanced chemical vapor deposition, and
forming a titanium nitride layer over the titanium layer by chemical vapor deposition.

49. The method of claim 48, wherein forming a titanium layer comprises providing a titanium containing gas through a first passageway of a showerhead.

50. The method of claim 49, wherein forming a titanium nitride layer comprises providing a titanium containing gas through the first passageway of the showerhead and providing a nitrogen containing gas through a second passageway of the showerhead.

51. The method of claim 50, wherein the first passageway comprises column holes and wherein the second passageway comprises groove holes.

52. The method of claim 50, wherein the titanium containing gas comprises titanium tetrachloride.

53. The method of claim 50, wherein the nitrogen containing gas comprises ammonia.

54. The method of claim 50, wherein depositing a titanium layer further comprises providing a hydrogen containing gas.

55. The method of claim 54, wherein the hydrogen containing gas is provided through the second passageway of the showerhead.

56. The method of claim 48, further comprising capping the titanium layer by a nitrogen plasma treatment of the titanium layer.

57. The method of claim 48, wherein forming a titanium layer by plasma enhanced chemical vapor deposition comprises forming a composite titanium/titanium nitride layer.

58. The method of claim 57, wherein forming a composite titanium/titanium nitride layer comprises performing a plurality of process cycles, the process cycle comprising:
depositing a titanium layer by plasma enhanced chemical vapor deposition; and
treating the titanium layer with a nitrogen plasma treatment.

59. The method of claim 48, further comprising treating the titanium nitride layer with a nitrogen plasma.
